(19) United States
(12) Patent Application Publication
(10) Pub. No.: US 2024/0407238 A1
(43) Pub. Date: Dec. 5, 2024

(54) DISPLAY MODULES AND MANUFACTURING METHODS THEREOF, AND DISPLAY PANELS

(71) Applicants: Yunnan Invensight Optoelectronics Technology Co., Ltd., Kunming, Yunnan (CN); Boe Technology Group Co., Ltd., Beijing (CN)

(72) Inventors: Yunhao ZHANG, Beijing (CN); Zongshun YANG, Beijing (CN); Hongtao YU, Beijing (CN); Dongdong SU, Beijing (CN); Kuanta HUANG, Beijing (CN); Weiliang BU, Beijing (CN); Chao YANG, Beijing (CN); Fushuang ZHANG, Beijing (CN); Cao WU, Beijing (CN)

(21) Appl. No.: 18/696,974

(22) PCT Filed: Jul. 6, 2023
(86) PCT No.: PCT/CN2023/105987

§ 371 Date: Mar. 28, 2024

(30) Foreign Application Priority Data
Jul. 29, 2022 (CN) 202210908665.7

(51) Int. Cl. H10K 59/80; H10K 59/12; H10K 59/38

(52) U.S. Cl. CPC H10K 59/879; H10K 59/1201; H10K 59/38; H10K 59/873

(57) ABSTRACT

The present disclosure relates to a display module, a manufacturing method thereof, and a display panel. The display module includes a light-emitting structure layer and a lens structure. The light-emitting structure layer includes a pixel unit layer including pixel units and a color filter layer on the pixel unit layer, where the color filter layer includes color filters respectively corresponding to the pixel units. The lens structure is on the light-emitting structure layer and includes lens units respectively corresponding to the color filters. The lens units are made of inorganic materials.

### TECHNICAL FIELD

The present disclosure belongs to the field of display technology, in particular to display modules, manufacturing methods thereof, and display panels.

### BACKGROUND

With the development of display panel technology, organic-light-emitting-diode (OLED) display devices have advantages of all-solid-state structure, high brightness, full view angle, fast response speed, and support for flexible displays, and become highly competitive and promising next-generation display structures. Micro-OLED display products, as a commonly used organic-light-emitting-diode display device, are widely used. In the Micro-OLED display, a lens structure is correspondingly provided on the light-emitting structure layer with a pixel unit, to improve the light-emitting effect of the Micro-OLED display. In related technologies, the lens structure is made of organic materials such as photoresist, and its refractive index is small, which makes the light emitted by the light-emitting structure layer have a certain reflectivity, affecting the overall light-emitting effect of the product.

### SUMMARY

According to the first aspect of the embodiments of the present disclosure, a display module is provided, and includes:
a light-emitting structure layer including a pixel unit layer with pixel units and a color filter layer on the pixel unit layer, where the color filter layer includes color filters respectively corresponding to the pixel units; and
a lens structure on the light-emitting structure layer, where the lens structure includes lens units respectively corresponding to the color filters, where the lens units are made of inorganic materials.

In some embodiments, the lens structure includes:
a lens body, where the lens body includes a first surface that is convex; and
an additional lens layer attached to the first surface of the lens body, where a shape of the additional lens layer is consistent with a shape of the first surface of the lens body.

In some embodiments, a material of the additional lens layer is the same as a material of the lens body.

In some embodiments, the additional lens layer includes a first additional lens layer on the lens body, a second additional lens layer on the first additional lens layer, and a third additional lens layer on the second additional lens layer.

In some embodiments, refractive indexes of the lens body, the first additional lens layer, the second additional lens layer, and the third additional lens layer are the same or sequentially increased.

In some embodiments, thicknesses of the lens body, the first additional lens layer, the second additional lens layer, and the third additional lens layer are sequentially reduced.

In some embodiments, the display module further includes: a protecting layer between the light-emitting structure layer and the lens structure.

In some embodiments, a material of the protecting layer includes Al2O3, ZnO, TiO2, ITO, or IZO; and/or,
thickness of the protecting layer is 400 Å to 500 Å; and/or,
a material of the lens structure includes SiNx; and/or,
a refractive index of the lens structure is greater than or equal to 1.88.

According to the second aspect of the embodiments of the present disclosure, a display panel is provided, and includes the display module as described above.

According to the third aspect of the embodiments of the present disclosure, a manufacturing method for a display module is provided, and includes:
providing a light-emitting structure layer, where the light-emitting structure layer includes a pixel unit layer with pixel units and a color filter layer on the pixel unit layer, where the color filter layer includes color filters respectively corresponding to the pixel units; and
providing a lens structure on the light-emitting structure layer, where the lens structure includes lens units respectively corresponding to the color filters, where the lens units are made of inorganic materials.

In some embodiments, providing the lens structure on the light-emitting structure layer includes:
forming an inorganic material layer on the light-emitting structure layer; and
etching the inorganic material layer to form the lens structure.

In some embodiments, after forming the inorganic material layer on the light-emitting structure layer, the manufacturing method includes:
providing an etching resist layer on the inorganic material layer:
etching the etching resist layer to form a transfer-printing lens structure, where a shape of the transfer-printing lens structure is consistent with a shape of the lens structure; and
etching the inorganic material layer by transfer printing to form the lens structure.

In some embodiments, the lens structure includes a lens body and an additional lens layer on the lens body, and etching the inorganic material layer by transfer printing to form the lens structure includes:
etching the inorganic material layer to form the lens body, where the lens body includes a first surface that is convex.

In some embodiments, after forming the lens body, the method includes:
forming the additional lens layer on the first surface of the lens body.

In some embodiments, the additional lens layer includes a first additional lens layer on the lens body, a second additional lens layer on the first additional lens layer, and a third additional lens layer on the second additional lens layer, and the manufacturing method further includes:
forming the first additional lens layer on the first surface of the lens body:
forming the second additional lens layer on the first additional lens layer; and
forming the third additional lens layer on the second additional lens layer, to form the lens structure.

In some embodiments, refractive indexes of the lens body, the first additional lens layer, the second additional lens layer, and the third additional lens layer are the same or sequentially increased.

In some embodiments, thicknesses of the lens body, the first additional lens layer, the second additional lens layer, and the third additional lens layer are sequentially reduced.

In some embodiments, before providing the lens structure on the light-emitting structure layer, the manufacturing method includes:
forming a protecting layer on the light-emitting structure layer.

In some embodiments, a material of the protecting layer includes Al2O3, ZnO, TiO2, ITO, or IZO; and/or,
thickness of the protecting layer is 400 Å to 500 Å; and/or,
a material of the lens structure includes SiNx; and/or,
a refractive index of the lens structure is greater than or equal to 1.88; and/or
transmittance of the lens structure is greater than 95% for 460 nm; and/or
transmittance of the lens structure is greater than 95% for 460 nm.

In the above-mentioned display module, manufacturing method thereof, and display device provided in the present disclosure, the lens structure formed by inorganic materials has a higher refractive index compared to existing lens structures formed by organic materials such as photoresists, which is conducive to making the focus of the lens structure closer to the light-emitting unit (pixel unit) of the light-emitting structure layer, improving the light transmittance and enhancing the light-emitting efficiency of the display module.

It is to be understood that the above general descriptions and the below detailed descriptions are merely exemplary and explanatory, and are not intended to limit the present disclosure.

### BRIEF DESCRIPTION OF DRAWINGS

The accompanying drawings herein, which are incorporated in and constitute a part of the present description, illustrate examples consistent with the present disclosure and serve to explain the principles of the present disclosure together with the description.

FIG. 1 is a schematic cross-sectional diagram of a display module according to an embodiment of the present disclosure.

FIG. 2 is a schematic cross-sectional diagram of a display module according to an embodiment of the present disclosure.

FIG. 3 is a flowchart of a manufacturing method for a display module according to an embodiment of the present disclosure.

FIGS. 4 to 10 are manufacturing process diagrams for a display module according to embodiments of the present disclosure.

FIGS. 11 to 25 are manufacturing process diagrams for a display module according to embodiments of the present disclosure.

### DETAILED DESCRIPTION

Embodiments will be described in detail herein, examples of which are illustrated in the accompanying drawings. Where the following description refers to the drawings, elements with the same numerals in different drawings refer to the same or similar elements unless otherwise indicated. Implementations described in the following embodiments do not represent all implementations consistent with the present disclosure. On the contrary, they are examples of an apparatus and a method consistent with some aspects of the present disclosure described in detail in the appended claims.

Terms used in the present disclosure is only for the purpose of describing particular embodiments and is not intended to limit the present disclosure. Unless otherwise defined, the technical terms or scientific terms used in the present disclosure shall have the ordinary meanings understood by those skilled in the art to which the present disclosure belongs. The words such as “a” or “an” in the specification and the claims of the present disclosure do not indicate a quantity limitation, but mean that there is at least one. “A plurality of” means two or more. “Include”, “comprise” and similar terms mean that the elements or items listed before “include” or “comprise” include the elements or items listed after “include” or “comprise” and their equivalents, and do not exclude other elements or objects. Words such as “connect” or “couple” are not limited to physical or mechanical connections, and can include electrical connections, whether direct or indirect. Words such as “top” and/or “bottom” are only for illustration purposes and are not limited to a single position or spatial orientation. As used in the present disclosure and the appended claims, the singular forms “a”, “said” and “the” are intended to include the plural”, and “the” are intended to include the plural forms as well, unless the context clearly dictates otherwise. It should further be understood that the term “and/or” as used herein refers to and includes any and all possible combinations of one or more of the associated listed items.

The present disclosure provides a display module, a manufacturing method thereof, and a display panel. The display module includes a light-emitting structure layer and a lens structure. The light-emitting structure layer includes a pixel unit layer including pixel units and a color filter layer on the pixel unit layer, where the color filter layer includes color filters respectively corresponding to the pixel units. The lens structure is on the light-emitting structure layer and includes lens units respectively corresponding to the color filters. The lens units are made of inorganic materials. In the above structure, the lens structure formed by inorganic materials has a higher refractive index compared to existing lens structures formed by organic materials such as photoresists, which is conducive to making the focus of the lens structure closer to the light-emitting unit (pixel unit) of the light-emitting structure layer, improving the light transmittance and enhancing the light-emitting efficiency of the display module.

The display panel referred to in the present disclosure can be a Micro-OLED display device, which can be applied to products or components with display functions such as mobile phones, tablets, televisions, laptops, etc., as a display panel for products or components with display functions such as mobile phones, tablets, televisions, laptops, etc.

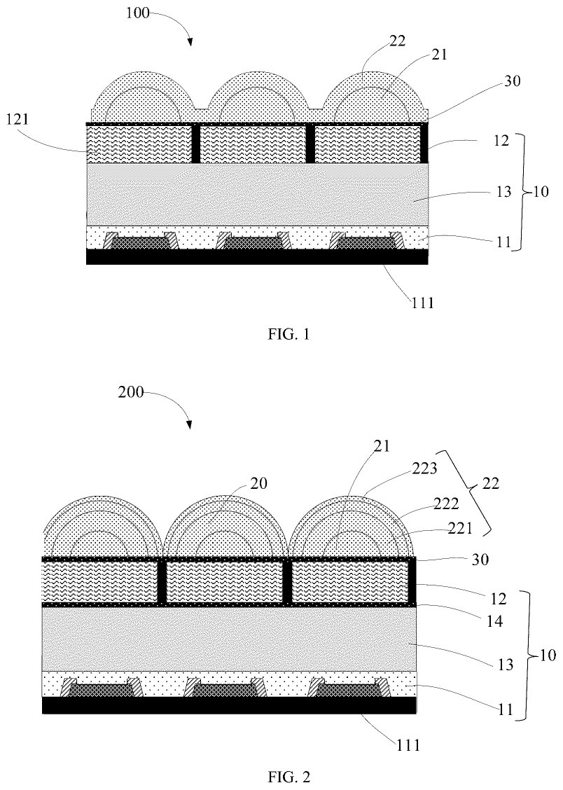

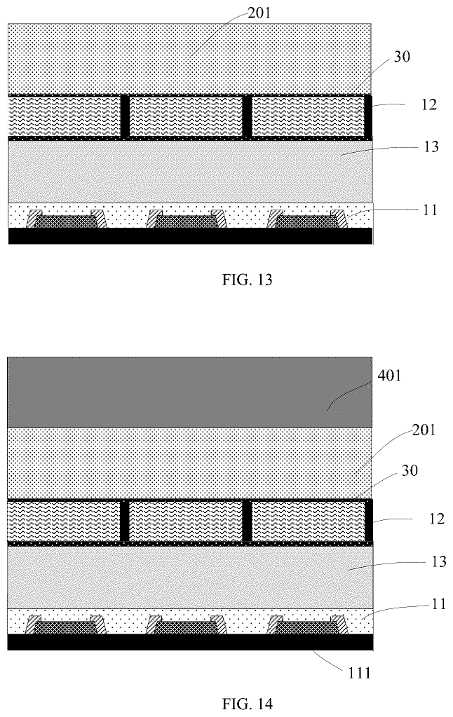

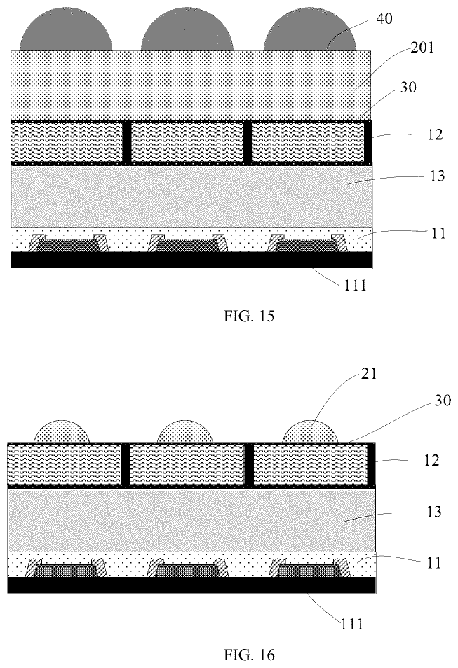

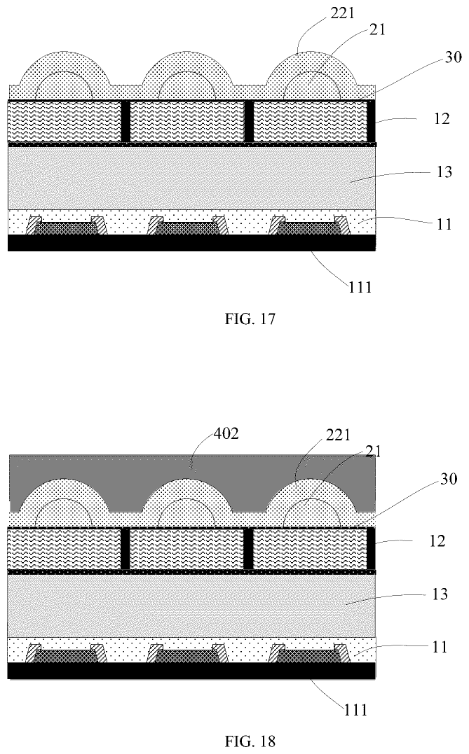

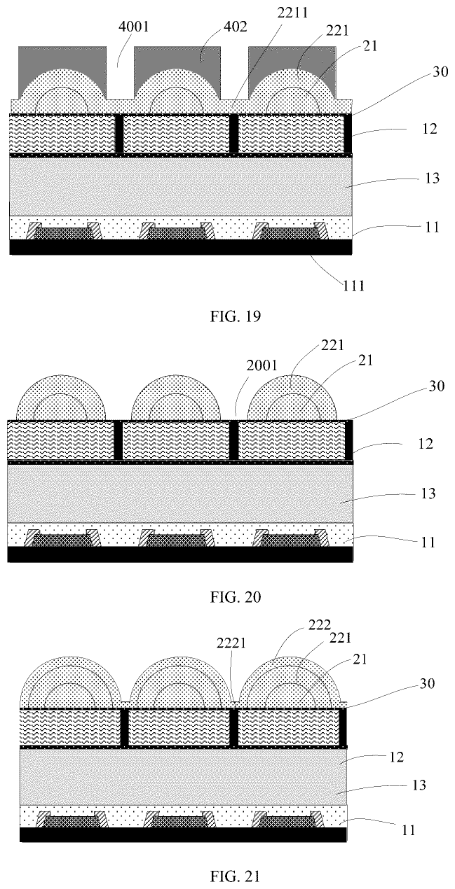

The display module and the manufacturing method thereof, and the display panel provided in the present disclosure will be described in detail below with reference to FIGS. 1 to 25.

Referring to FIG. 1, the present disclosure provides a display module 100. The display module 100 includes a light-emitting structure layer 10 and a lens structure 20. The light-emitting structure layer 10 includes a pixel unit layer 11 with pixel units 111 and a color filter layer 12 on the pixel unit layer 11. The color filter layer 12 includes color filters 121 respectively corresponding to the pixel units 111. The lens structure 20 is on the light-emitting structure layer 10, and includes lens units 202 respectively corresponding to the color filters 121. The lens units 202 are made of inorganic materials.

A substrate can also be provided under the light-emitting structure layer 10, such as an array substrate with a driving circuit layer.

In some embodiments, the material of the lens structure 20 includes SiNx or other similar inorganic materials with higher refractive indices.

In some embodiments, the refractive index of the lens structure 20 is greater than or equal to 1.88.

In some embodiments, the transmittance of the lens structure is greater than 95% for 460 nm, that is, the transmittance of the lens structure for light with a wavelength of 460 nm or approximately 460 nm is greater than 95%, to ensure the transmittance of light.

In some embodiments, the lens structure 20 includes a lens body 21 and an additional lens layer 22.

The lens body 21 includes an externally convex first surface. An additional lens layer 22 is attached to the first surface of the lens body 21, where a shape of the additional lens layer 22 is consistent with a shape of the first surface of the lens body 21.

The additional lens layer 22 can be formed by chemical vapor deposition (CVD).

The additional lens layer 22 is basically completely adhered to the first surface of the lens body 21. However, since the lens body 21 and the additional lens layer 22 are separately manufactured, an extremely thin interface layer will be formed on the contact surface of the lens body 21 and the additional lens layer 22. The interface layer only has a thickness of only about 4-5 angstroms, and has little effect on the optical performance of the display module 100.

In some embodiments, a material of the additional lens layer 22 is the same as a material of the lens body 21.

In some embodiments, a protecting layer 30 is provided between the light-emitting structure layer 10 and the lens structure 20.

A material of the protecting layer 30 includes Al2O3, ZnO, TiO2, ITO, or IZO.

The thickness of the protecting layer 30 can be 400 Å to 500 Å to protect the color filter layer 12 without affecting the propagation of light within the structure.

Referring to FIG. 2, the present disclosure provides another display module 200. The display module 200 has a similar structure to the above display module 100. The difference is that the additional lens layer 22 in the display module 100 mentioned above is a single-layer structure. The additional lens layer 22 in the display module 200 includes a first additional lens layer 221 on the lens body 21, a second additional lens layer 222 on the first additional lens layer 221, and a third additional lens layer 223 on the second additional lens layer 222.

The additional lens layers here can also be formed by chemical vapor deposition (CVD).

In some embodiments, the refractive indexes of the lens body 21, the first additional lens layer 221, the second additional lens layer 222, and the third additional lens layer 223 are the same or sequentially increased, such that the refractive index of the lens body 21 and all additional lens layers increases in a gradient, which is conducive to reducing the light reflectivity and further improving the optical performance of the product.

In some embodiments, thicknesses of the lens body 21, the first additional lens layer 221, the second additional lens layer 222, and the third additional lens layer 223 are sequentially reduced.

For example, in some embodiments, the maximum diameter (hereinafter referred to as the diameter) of the orthographic projection of the lens body 21 can be 2.8 μm, and the height can be 1.6 μm. The thickness of the first additional lens layer 221 can be 0.3 μm. The thickness of the second additional lens layer 222 can be 0.2 μm. The thickness of the third additional lens layer 223 can be 0.1 μm. Due to the limitation of step coverage in vapor deposition, when additional lens layers are formed to increase the dimensions of lens unit, for every 0.1 μm of thickness of the additional lens layer increased in the lens unit, the height of the entire lens unit can be increased by 0.1 μm, and the diameter of the lens unit can be increased by approximately 0.07 μm. Therefore, the lens unit 202 formed in this embodiment can reach a height of 2.1 μm, and a diameter of approximately 3.2 μm.

In addition, the first surface of the lens body 21 in the lens unit 202 can be away from the light-emitting structure layer 10 or towards the light-emitting structure layer 10, which is not limited in the present disclosure.

The present disclosure further provides a manufacturing method for a display module. The manufacturing method can be used to manufacture the above display module 100 and display module 200. The manufacturing method of the display module includes steps S101 and S103 as follows.

In S101, a light-emitting structure layer is provided, where the light-emitting structure layer includes a pixel unit layer with pixel units and a color filter layer on the pixel unit layer, where the color filter layer includes color filters respectively corresponding to the pixel units.

In S103, a lens structure is provided on the light-emitting structure layer, where the lens structure includes lens units respectively corresponding to the color filters, where the lens units are made of inorganic materials.

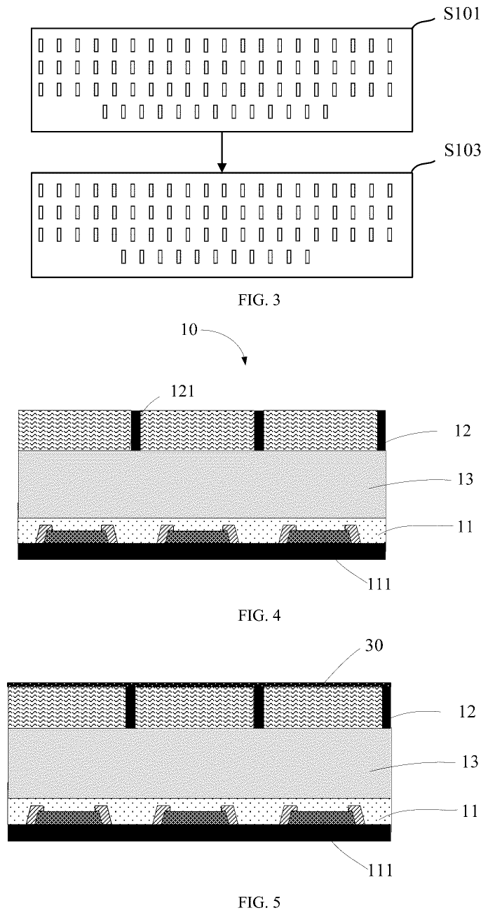

Here, a detailed description is first provided for the manufacturing methods for the display module 100 and display modules similar to the display module 100. Referring to FIG. 3, and if necessary, combined with FIGS. 4 to 10, in some embodiments,
as shown in FIG. 4, in S101, a light-emitting structure layer 10 is provided, where the light-emitting structure layer 10 includes a pixel unit layer 11 with pixel units 111 and a color filter layer 12 on the pixel unit layer 11, where the color filter layer 12 includes color filters 121 respectively corresponding to the pixel units 111.

A substrate can also be provided under the light-emitting structure layer 10, such as an array substrate with a driving circuit layer.

Providing the light-emitting structure layer mentioned here can be understood as providing the light-emitting structure layer on the substrate, that is, providing the component composed of the substrate and the light-emitting structure layer.

As shown in FIG. 5, before S103, the manufacturing method includes the following steps S102.

In step S102, a protecting layer 30 is formed on the light-emitting structure layer 10.

In some embodiments, a material of the protecting layer 30 includes Al2O3, ZnO, TiO2, ITO, or IZO.

The thickness of the protecting layer 30 can be 400 Å to 500 Å to protect the color filter layer 12 without affecting the propagation of light within the structure. The protecting layer can be formed by atomic layer deposition (ALD) under a low temperature condition (such as 90° C.), so as not to affect the color filter layer 12 and other structures under the protecting layer during the manufacturing process.

In some embodiments, step S103 can be achieved through steps S1031 and S1033 as follows.

In S1031, an inorganic material layer 201 is formed on the light-emitting structure layer 10.

In S1033, the inorganic material layer 201 is etched to form the lens structure 20.

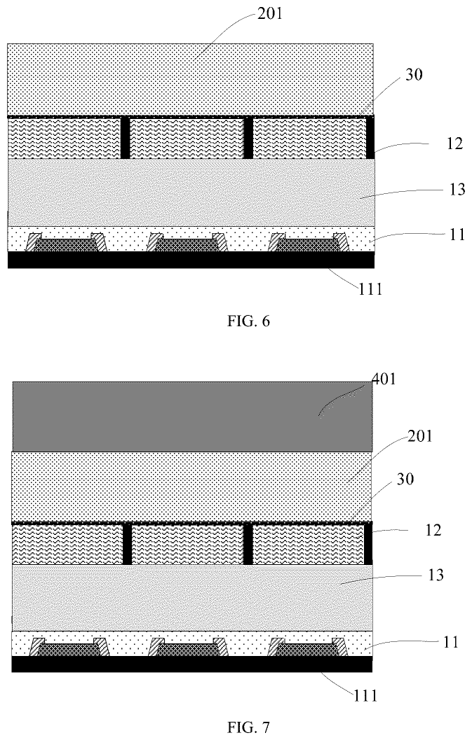

As shown in FIG. 6, the inorganic material layer 201 can be an inorganic material such as silicon oxide. The inorganic material layer 201 can be formed by chemical vapor deposition (CVD).

The thickness of the inorganic material layer 201 can be determined based on specific circumstances. For example, in some embodiments, the thickness of the inorganic material layer 201 can be 2 μm to 2.2 μm. In other embodiments, the inorganic material layer can also be manufactured to other thicknesses, which is not limited in the present disclosures.

In some embodiments, step S1032 can be specifically implemented through steps S1321 to S1323 as follows.

In step S1321, an etching resist layer 401 is provided on the inorganic material layer 201.

In step S1322, the etching resist layer 401 is etched to form a transfer-printing lens structure 40. The shape of the transfer-printing lens structure 40 is consistent with the shape of the lens structure 20.

In step S1323, the inorganic material layer 201 is etched by transfer printing to form the lens structure 20.

As shown in FIG. 7, a layer of etching resist material is coated on the surface of the inorganic material layer 201 to form an etching resist layer 401.

The material of the etching resist layer 401 can be an organic photosensitive material used for manufacturing lens units in relevant technologies.

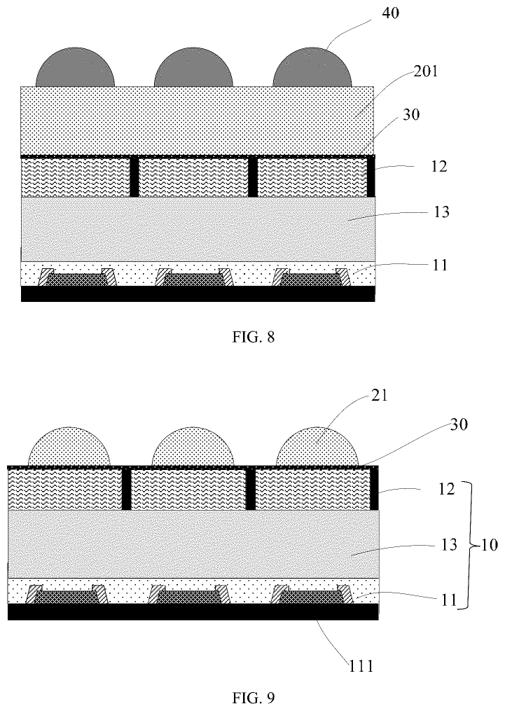

As shown in FIG. 8, the etching resist layer 401 can be etched by exposing, developing, and other methods to form the transfer-printing lens structure 40. The transfer-printing lens structure 40 includes spaced transfer-printing lens units.

The dimensions of the transfer-printing lens structure 40 can be set according to specific circumstances. In some embodiments, the diameter of the transfer-printing lens structure 40 can be 3.6 μm, and the height can be 2.2 μm.

The consistency between the shape of the transfer-printing lens structure 40 and the shape of the lens structure 20 mentioned here can be understood as the transfer-printing lens structure 40 and the lens structure 20 having the same shape, but dimensions of corresponding parts being in the same proportion.

The lens structure 20 includes a lens body 21 and an additional lens layer 22 on the surface of the lens body 21. Correspondingly, in step S1323, the inorganic material layer 201 is etched by transfer printing to form the lens structure 20, which can be understood as:

as shown in FIG. 9, the inorganic material layer 201 is etched to form lens bodies 21 respectively corresponding to the transfer-printing lens units. The lens body 21 includes an externally convex first surface. The shape of the lens body 21 is consistent with the shape of the transfer-printing lens unit, and the lens bodies 21 are spaced apart.

It should be noted that when transfer-printing etching is performed on the inorganic material layer 201 to form the lens body 21, the transfer printing can be performed by plasma etching the material. And when using plasma materials for etching, the corresponding transfer-printing lens structure can be determined according to specific needs, and the etching ratios of the plasma material to an organic material interface and an inorganic material interface can be adjusted according to specific needs, to obtain the required lens bodies 21. For example, the dimensions of the transfer-printing structure can generally be set to be consistent (can be understood as roughly consistent) with the required dimensions of the lens structure.

Based on the different etching ratios of the etching material to the organic material interface and the inorganic material interface during the transfer-printing process, most etching materials etch inorganic materials at a faster rate than organic materials under the same conditions, resulting in the lens body 21 formed after transfer printing being slightly smaller in dimensions than the transfer-printing lens unit in the transfer-printing lens structure. In some embodiments, an additional lens layer 22 can be provided on the surface of the lens body 21, to reduce or even eliminate the reduction in the dimensions of the lens unit caused by the transfer printing, such that the dimensions of the formed lens unit is similar to the dimensions of the transfer-printing lens unit of the transfer-printing lens structure.

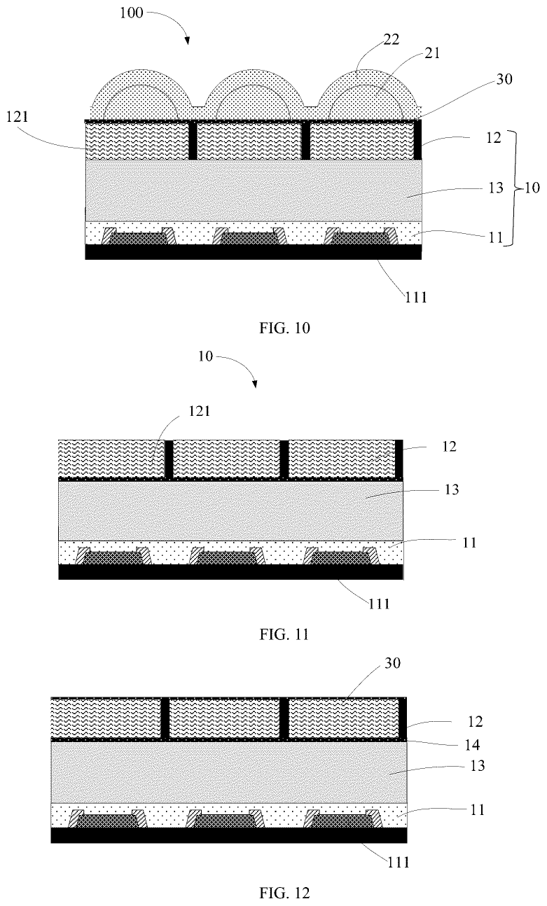

As shown in FIG. 10, after the lens bodies 21 are formed, a layer of inorganic material is deposited on the first surface of the lens bodies 21 by CVD or other methods to form an additional lens layer 22, thereby forming a display module 100 with a single additional lens layer 22 on the lens bodies 21.

The thickness of the additional lens layer 22 can be set according to specific circumstances.

Below is a detailed description of the manufacturing method for the display module 200 and similar display modules with a plurality of the additional lens layers. Roughly the same as the manufacturing method for the display module 100 shown in FIGS. 4 to 10 above, similarities or commonalities can be referred to the relevant description above. Here, the differences will be mainly explained. Referring to FIGS. 11 to 25, the additional lens layer 22 in the display module 200 includes a first additional lens layer 221 on the lens body 21, a second additional lens layer 222 on the first additional lens layer 221, and a third additional lens layer 223 on the second additional lens layer 222. Correspondingly, different from the manufacturing method for the display module 100 mentioned above, after the lens bodies 21 are formed in step S1323, the method further includes the following steps S13231 to S13233.

In step S13231, a first additional lens layer 221 is formed on the first surface of the lens body 21.

In step S13232, a second additional lens layer 222 is formed on the surface of the first additional lens layer 221.

In step S13233, a third additional lens layer 223 is provided on the surface of the second additional lens layer 222, to form the lens structure 20.

As shown in FIGS. 18 to 20, after forming the first additional lens layer 221 and before forming the second additional lens layer 222, the portion 2211 of the inorganic material layer deposited between adjacent lens bodies 21 can be removed by photolithography, to ensure consistency between the lens structure and the transfer-printing lens structure 40 when providing the second additional lens layer 222. In some embodiments, corresponding photoresist layers 402 is coated on the first additional lens layers 221 to form a through-hole 4001 between adjacent lens bodies 21. Then, the portion 2211 of the inorganic material layer in the through-hole 4001 is etched, and then, the remaining photoresist layers 402 is removed.

As shown in FIG. 21, an inorganic material layer is deposited on the structure formed in FIG. 20, to form a second additional lens layer 222.

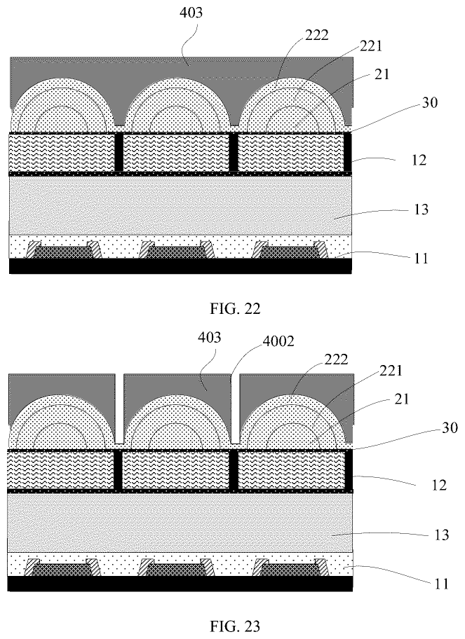

As shown in FIGS. 22 to 24, after forming the second additional lens layer 222 and before forming the third additional lens layer 223, the portion 2221 of the inorganic material layer deposited between adjacent lens bodies 21 can be removed by photolithography, to ensure consistency between the lens structure and the transfer-printing lens structure 40 when providing the third additional lens layer 223. In some embodiments, corresponding photoresist layers 403 is coated on the second additional lens layers 222 to form a through-hole 4002 between adjacent lens bodies 21. Then, the portion 2221 of the inorganic material layer in the through-hole 4002 is etched, and then, the remaining photoresist layers 403 is removed.

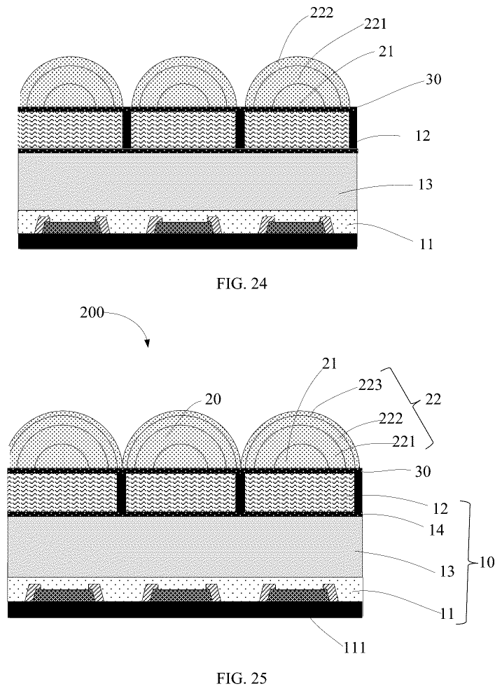

As shown in FIG. 25, an inorganic material layer is deposited on the structure formed in FIG. 24, to form a third additional lens layer 223.

In some embodiments, refractive indexes of the lens body 21, the first additional lens layer 221, the second additional lens layer 222, and the third additional lens layer 223 are the same or sequentially increased.

In some embodiments, thicknesses of the lens body 21, the first additional lens layer 221, the second additional lens layer 222, and the third additional lens layer 223 are sequentially reduced.

The specific details of the lens body 21 of the lens structure 20 and the structure of each additional lens layer can be referred to in the above description, and will not be elaborated here.

It should be noted that an extremely thin interface layer can be formed at the contact surface between the lens body 21 and the first additional lens layer 221, and at the contact surface between each adjacent additional lens layers. The interface layer only has a thickness of only about 4-5 angstroms, and has little effect on the optical performance of the display module 200.

In addition, it should be noted that in other embodiments, the etching ratios of the plasma etching material to the organic material interface and the inorganic material interface can be adjusted, and the dimensions of the transfer-printing lens structure can be adjusted, to form a complete lens unit through one-time transfer-printing etching. which is not limited in the present disclosure, and can be set according to specific circumstances. The present disclosure further provides a display panel. The display panel includes the display module as described above. The display panel can be a Micro-OLED display device, which can be applied to products or components with display functions such as mobile phones, tablets, televisions, laptops, etc., as a display panel for products or components with display functions such as mobile phones, tablets, televisions, laptops, etc.

In the present disclosure, the structural embodiments and method embodiments can complement each other without conflict.

In the present disclosure, the terms “first” and “second” are only for descriptive purposes, and cannot be understood as indicating or implying relative importance. The term “plurality of” and “several” means two or more, unless otherwise clearly defined.

After considering and practicing the disclosure of the specification, other embodiments of the present disclosure will be readily apparent to those skilled in the art. The present disclosure is intended to cover any modification, use or adaptation of the present disclosure. These modifications, uses or adaptations follow the general principles of the present disclosure and include common knowledge and conventional technical means in the technical field that are not disclosed in the present disclosure. The specification and embodiments herein are intended to be illustrative only and the real scope and spirit of the present disclosure are indicated by the claims of the present disclosure.

It is to be understood that the present disclosure is not limited to the precise structures described above and shown in the accompanying drawings and can be modified or changed without departing from the scope of the present disclosure. The scope of protection of the present disclosure is limited only by the appended claims.

1. A display module, comprising:
a light-emitting structure layer comprising a pixel unit layer with pixel units and a color filter layer on the pixel unit layer, wherein the color filter layer comprises color filters respectively corresponding to the pixel units; and
a lens structure on the light-emitting structure layer, wherein the lens structure comprises lens units respectively corresponding to the color filters, wherein the lens units are made of inorganic materials.

2. The display module according to claim 1, wherein the lens structure comprises:
a lens body, wherein the lens body comprises a first surface that is convex; and
an additional lens layer attached to the first surface of the lens body, wherein a shape of the additional lens layer is consistent with a shape of the first surface of the lens body.

3. The display module according to claim 2, wherein a material of the additional lens layer is the same as a material of the lens body.

4. The display module according to claim 2, wherein the additional lens layer comprises a first additional lens layer on the lens body, a second additional lens layer on the first additional lens layer, and a third additional lens layer on the second additional lens layer.

5. The display module according to claim 4, wherein refractive indexes of the lens body, the first additional lens layer, the second additional lens layer, and the third additional lens layer are the same or sequentially increased.

6. The display module according to claim 4, wherein thicknesses of the lens body, the first additional lens layer, the second additional lens layer, and the third additional lens layer are sequentially reduced.

7. The display module according to claim 1, further comprising:
a protecting layer between the light-emitting structure layer and the lens structure.

8. The display module according to claim 7, wherein
a material of the protecting layer comprises Al2O3, ZnO, TiO2, ITO, or IZO; and/or,
thickness of the protecting layer is 400 Å to 500 Å; and/or,
a material of the lens structure comprises SiNx; and/or,
a refractive index of the lens structure is greater than or equal to 1.88; and/or
transmittance of the lens structure is greater than 95% for a wavelength of 460 nm.

9. A display panel, comprising a display module, wherein the display module comprises:
a light-emitting structure layer comprising a pixel unit layer with pixel units and a color filter layer on the pixel unit layer, wherein the color filter layer comprises color filters respectively corresponding to the pixel units; and
a lens structure on the light-emitting structure layer, wherein the lens structure comprises lens units respectively corresponding to the color filters, wherein the lens units are made of inorganic materials.

10. A manufacturing method for a display module, comprising:
providing a light-emitting structure layer, wherein the light-emitting structure layer comprises a pixel unit layer with pixel units and a color filter layer on the pixel unit layer, wherein the color filter layer comprises color filters respectively corresponding to the pixel units; and
providing a lens structure on the light-emitting structure layer, wherein the lens structure comprises lens units respectively corresponding to the color filters, wherein the lens units are made of inorganic materials.

11. The manufacturing method according to claim 10, wherein providing the lens structure on the light-emitting structure layer comprises:
forming an inorganic material layer on the light-emitting structure layer; and
etching the inorganic material layer to form the lens structure.

12. The manufacturing method according to claim 11, wherein the manufacturing method comprises:
providing an etching resist layer on the inorganic material layer;
etching the etching resist layer to form a transfer-printing lens structure, wherein a shape of the transfer-printing lens structure is consistent with a shape of the lens structure; and
etching the inorganic material layer by transfer printing to form the lens structure.

13. The manufacturing method according to claim 12, wherein etching the inorganic material layer by transfer printing to form the lens structure comprises:
etching the inorganic material layer to form a lens body, wherein the lens body comprises a first surface that is convex.

14. The manufacturing method according to claim 13, wherein the manufacturing method further comprises:
forming an additional lens layer on the first surface of the lens body.

15. The manufacturing method according to claim 14, wherein comprises:
forming a first additional lens layer on the first surface of the lens body;
forming a second additional lens layer on the first additional lens layer; and
forming a third additional lens layer on the second additional lens layer, to form the lens structure.

16. The manufacturing method according to claim 15, wherein refractive indexes of the lens body, the first additional lens layer, the second additional lens layer, and the third additional lens layer are the same or sequentially increased.

17. The manufacturing method according to claim 15, wherein thicknesses of the lens body, the first additional lens layer, the second additional lens layer, and the third additional lens layer are sequentially reduced.

18. The display module according to claim 10, wherein the manufacturing method further comprises:
forming a protecting layer on the light-emitting structure layer.

19. The manufacturing method according to claim 18, wherein
a material of the protecting layer comprises Al2O3, ZnO, TiO2, ITO, or IZO; and/or,
thickness of the protecting layer is 400 Å to 500 Å; and/or,
a material of the lens structure comprises SiNx; and/or,
a refractive index of the lens structure is greater than or equal to 1.88; and/or
transmittance of the lens structure is greater than 95% for 460 nm.

20. The display panel according to claim 9, wherein the lens structure comprises:
a lens body, wherein the lens body comprises a first surface that is convex; and
an additional lens layer attached to the first surface of the lens body, wherein a shape of the additional lens layer is consistent with a shape of the first surface of the lens body.
